(19) United States
(12) Patent Application Publication
(10) Pub. No.: US 2024/0402038 A1
(43) Pub. Date: Dec. 5, 2024

(54) APPARATUSES, TEST CARDS AND METHODS FOR TESTING PHOTONIC INTEGRATED CIRCUITS, AND PHOTONIC INTEGRATED CIRCUITS

(71) Applicant: Carl Zeiss SMT GmbH, Oberkochen (DE)

(72) Inventors: Heiner Zwickel, Karlsruhe (DE); Stefan Richter, Jena (DE); Tobias Harter, Karlsruhe (DE)

(21) Appl. No.: 18/799,060

(22) Filed: Aug. 9, 2024

Related U.S. Application Data
(63) Continuation of application No. PCT/EP2023/053095, filed on Feb. 8, 2023.

(30) Foreign Application Priority Data
Feb. 16, 2022 (DE) 10 2022 103 611.1

(51) Int. Cl. G01M 11/02

(52) U.S. Cl. CPC G01M 11/0207

(57) ABSTRACT

Apparatuses and test cards for testing photonic integrated circuits, corresponding systems and methods, and photonic integrated circuits are provided. A test card can be imaged via an optical unit onto a photonic integrated circuit to be tested. Parallel illumination of the photonic integrated circuit at different locations is possible in this way.

### CROSS-REFERENCE TO RELATED APPLICATIONS

The present application is a continuation of, and claims benefit under 35 USC 120 to, international application No. PCT/EP2023/053095, filed Feb. 8, 2023, which claims benefit under 35 USC 119 of German Application No. 102022103611.1, filed Feb. 16, 2022. The entire disclosure of each of these applications is incorporated by reference herein.

### FIELD

The present disclosure relates to apparatuses, test cards and methods for testing photonic integrated circuits (PICs), and to photonic integrated circuits configured for such tests.

### BACKGROUND

In photonic integrated circuits, in a manner similar to that in the case of electronic integrated circuits, a multiplicity of passive and/or active optical and optoelectronic components are assembled on a common substrate, for example a semiconductor wafer, to form complex optical circuits. In this case, traditional optical components such as filters or couplers, for example, can be replaced by more compact integrated optical components. The various components of the photonic integrated circuit are connected to one another via waveguides in the photonic integrated circuit. Such photonic integrated circuits have become more interesting in recent years inter alia with the major growth in data traffic on the Internet, since signal processing circuits which have sufficient bandwidth and which operate efficiently are used here. Apart from telecommunications and data transmission applications, photonic integrated circuits are also of interest for other applications such as, for example, sensor technology and for applications in the life sciences.

The production process of such photonic integrated circuits resembles the production process of conventional electronic integrated circuits or microelectromechanical systems (MEMS). In contrast to these conventional technologies, however, for photonic integrated circuits, in general, only a small number of test methods exist that can be used to efficiently check such circuits during the production process or afterwards.

For testing the photonic integrated circuits, for example the waveguide structures located therein, light is coupled into the waveguide structures of the photonic integrated circuit and light is detected from the photonic integrated circuit, for example from the waveguide structures, or both.

One conventional method for testing such photonic integrated circuits uses light-guiding fibres, such as optical fibres or other dielectric light waveguides, which are aligned and positioned on the photonic integrated circuit to be tested. Using these light-guiding fibres, the photonic integrated circuit to be tested is then illuminated at corresponding input coupling points, and light emanating from the photonic integrated circuit is collected and then evaluated. This can involve a relatively high positioning accuracy in the range of <1 μm, which can involve a comparatively long time for positioning purposes and is therefore suitable only to a limited extent for large numbers of items.

DE 102017101626 A1, filed by the the present applicant, provides an apparatus for testing photonic integrated circuits in which a light beam is directed onto a circuit to be tested via a scanning device. This obviates complex positioning of the light-guiding fibres. However, a movable, correspondingly precise scanning mirror is used.

### SUMMARY

There is a desire for further possibilities for efficiently testing photonic integrated circuits.

In accordance with one aspect, an apparatus for testing photonic integrated circuits is provided, comprising: a receptacle for a test card having a plurality of light ports; and an optical unit for imaging the test card onto a photonic integrated circuit to be tested. Using the optical unit, light emanating from the test card can be imaged onto corresponding points to be illuminated of one or a plurality of photonic integrated circuits and, consequently, the photonic integrated circuit can be illuminated at a plurality of points for test purposes. Conversely, in a corresponding manner, light from the photonic integrated circuit can be received. Such an optical unit can be embodied in a manner known per se, e.g. as a microscope optical unit. The optical unit can effect reducing or magnifying imaging. Accordingly, the test card can then be made (to scale) larger or smaller than the photonic integrated circuit to be tested. A light port can be a light inlet or a light outlet, or function as such.

The apparatus can further comprise a receptacle for a further test card having light inlets, wherein the optical unit comprises a splitter element configured to pass on light from the test card to the photonic integrated circuit and to pass on light from the photonic integrated circuit to the further test card.

In this regard, it is possible to use separate test cards for the illumination and the detection.

The splitter element can comprise a polarization beam splitter. This can allow the illumination light beam and the detection light beam to be separated with relatively few losses.

The apparatus can further comprise a scanner device in a light path from the receptacle to the photonic integrated circuit. With this approach, for example, a plurality of photonic integrated circuits on a wafer can be scanned sequentially.

In accordance with a further aspect, a test card for testing a photonic integrated circuit is provided, comprising a multiplicity of light outlets for illuminating the photonic integrated circuit, which are arranged in a manner corresponding to locations of the photonic integrated circuit that are to be illuminated for the purpose of testing.

With such a test card and the apparatus mentioned above, a test of the respective photonic integrated circuit can be made possible in a simple manner.

The test card can further comprise a light source connected to the light outlets via at least one optical fibre. In this regard, the photonic integrated circuit to be tested can be illuminated with light from the light source. In this case, the term “light source” also encompasses arrangements having a plurality of individual light sources, e.g. light-emitting diodes, which are then connected to respectively assigned light outlets by respectively assigned optical fibres.

In one variant, the light outlets can correspond to ends of the at least one optical fibre. The ends can then still be connected to an attachment optical unit.

In a variant, the test card comprises a photonic integrated circuit. In this regard, it is possible to integrate various components for the purpose of testing.

Additionally or alternatively, the test card can comprise an electro-optical circuit board. There are various possibilities for implementation.

The light outlets can be configured to output polarized light for example by virtue of embodiment as grating couplers. Such a test card can then be used for example with the above-described apparatus that uses a polarization beam splitter.

The test card can furthermore comprise a multiplicity of light inlets for receiving light from the photonic integrated circuit, which are arranged in a manner corresponding to light-emitting locations of the photonic integrated circuit, which emit light during testing of the photonic integrated circuit. Such a test card can be used both for illumination purposes and for detection purposes.

In accordance with a further aspect, a test card for testing a photonic integrated circuit is provided, comprising a multiplicity of light inlets for receiving light from the photonic integrated circuit, which are arranged in a manner corresponding to light-emitting locations of the photonic integrated circuit, which emit light during testing of the photonic integrated circuit. Such a test card can be used for example as a further test card in the above-described apparatus with splitter element.

In accordance with a further aspect, a system for testing photonic integrated circuits is provided, comprising an apparatus as described above and a test card as described above, the test card being received in the receptacle.

The system can further comprise a circuit board, which is configured for contacting the photonic integrated circuit and which comprises: at least one electrical conductor track extending between a front side of the circuit board and a rear side of the circuit board and configured to contact an electrical interface of the photonic integrated circuit positioned adjacent to the rear side.

In this regard, an electrical contacting of the photonic integrated circuit to be tested can additionally be effected.

The circuit board can be an electro-optical circuit board, which additionally comprises at least one optical beam path extending between the front side of the electro-optical circuit board and the rear side of the electro-optical circuit board and configured to contact an optical interface of the photonic integrated circuit positioned adjacent to the rear side.

In accordance with a further aspect, a photonic integrated circuit is provided, comprising a test structure having an input coupling element for coupling in light having a first polarization and an output coupling element for coupling out light having a second polarization, which is different from the first polarization, wherein the input coupling element and the output coupling element are optically connected to the photonic integrated circuit. Such a photonic integrated circuit can be tested by an apparatus as described above that uses a polarization beam splitter.

The photonic integrated circuit can further comprise a sawing line between the input coupling element and the output coupling element, on the one hand, and the photonic integrated circuit, on the other hand. After the test, separation can then be performed along the sawing line, as a result of which edge couplers can arise, and the photonic integrated circuit can then be supplied for its use.

The input coupling element and the output coupling element can be formed as a common element. This can help save space.

The photonic integrated circuit can further comprise at least one combined input/output coupling element for alignment purposes, which is optically short-circuited with a waveguide.

This is also possible independently of the test structure mentioned above, such that, in accordance with a further aspect, a photonic integrated circuit is provided, comprising at least one combined input/output coupling element for alignment purposes, which is optically short-circuited with a waveguide. Such short-circuited input/output coupling elements make it possible to facilitate alignment of the test card in the systems described above.

In accordance with a further aspect, a method for testing a photonic integrated circuit using the apparatus described above is provided, comprising: inserting a test card described above into the receptacle; aligning the test card (e.g. With the aid of the short-circuited input/output coupling elements); and testing the photonic integrated circuit via the test card, such as by illuminating with the test card and detecting light emanating from the photonic integrated circuit via the test card or a further test card.

Various exemplary embodiments will now be explained with reference to the accompanying drawings.

### BRIEF DESCRIPTION OF THE DRAWINGS

FIG. 1 is a block diagram of a system in accordance with one exemplary embodiment.

FIG. 2 is an illustration of a system in accordance with one exemplary embodiment.

FIGS. 3A and 3B show test cards in accordance with different exemplary embodiments.

FIG. 4A is a diagram for elucidating polarization-based separation in accordance with some exemplary embodiments.

FIG. 4B shows a modification of FIG. 4A.

FIG. 5 shows a system in accordance with one exemplary embodiment.

FIG. 6 shows a system in accordance with one exemplary embodiment.

FIG. 7 elucidates the provisions of test structures in the case of some exemplary embodiments of photonic integrated circuits.

FIG. 8 elucidates the provision of alignment structures in the case of some exemplary embodiments of photonic integrated circuits.

FIG. 9 shows a flow diagram for illustrating a method for testing photonic integrated circuits using the systems described above.

FIG. 10 shows a block diagram of a further system with an additional electro-optical circuit board, in accordance with one exemplary embodiment.

### DETAILED DESCRIPTION

Various exemplary embodiments are explained in detail below. These exemplary embodiments are provided for illustration only and should not be construed as limiting. Features of different exemplary embodiments (for example components, method steps, elements and the like) can be combined with one another, even if this is not explicitly indicated. Variations, modifications and details that are described for one of the exemplary embodiments are also applicable to other exemplary embodiments and are therefore not explained repeatedly. Besides the features explicitly illustrated and described, other features, such as features of conventional apparatuses for testing photonic integrated circuits and of corresponding photonic integrated circuits, can also be provided. Such conventional features will not be explicitly explained.

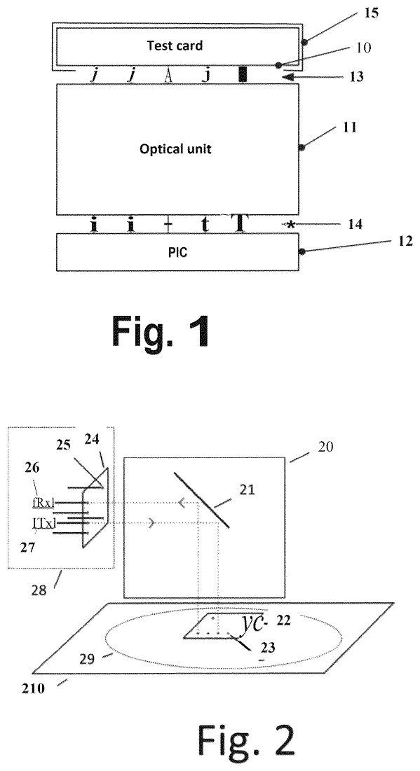

FIG. 1 shows a system for testing a photonic integrated circuit 12 in accordance with one exemplary embodiment. The system in FIG. 1 comprises an optical unit 11 and a test card 10, which is coordinated with the photonic integrated circuit 12 to be tested. The optical unit 11 images the test card 10 onto the photonic integrated circuit 12. In this case, the test card 10 comprises light outlets, light inlets, or both, such as light ports, which are indicated by arrows 13. These are imaged by the optical unit 11 onto the photonic integrated circuit 12, such that the latter is illuminated at points corresponding to the light outlets of the test card 10 and/or the test card 10 correspondingly receives at light inlets light emitted by the photonic integrated circuit 12 in response to illumination, as also indicated by arrows 14. In other words, the test card 10 and the photonic integrated circuit 12 are arranged in an object plane and an assigned image plane of the optical unit 11. In this case, a corresponding mount 15 or other receptacle can be provided for the test card 10. The receptacle can be alignable, for example by way of micrometre screw gauges, piezo elements and the like, in order to enable a precise arrangement of the test card 10. By virtue of the provision of such a receptacle, a corresponding test card for a type of photonic integrated circuit to be tested can be inserted in each case into the system in FIG. 1. In other exemplary embodiments, the test card is installed fixedly (not interchangeably) in the receptacle. In this case, only one type of photonic integrated circuits can be tested.

Here the test card 10 can comprise, for example, a plurality of light outlets at a plurality of locations, such that the photonic integrated circuit 12 can be illuminated simultaneously at a plurality of points. Conversely, the light from a plurality of points of the photonic integrated circuit 12 can also be received simultaneously at various light inlets and then be correspondingly evaluated. Consequently, according to the dimensioning of the optical unit 11 and the test card 10, simultaneous testing of areas of corresponding size on the photonic integrated circuit 12 is possible. By way of example, an entire photonic integrated circuit 12 can be tested in parallel, or a plurality of photonic integrated circuits arranged on a wafer can also be tested in parallel, if the test card 10 is of corresponding size and the optical unit 11 is dimensioned correspondingly. However, the photonic integrated circuit 12 can also be movable, for example be arranged on a sample stage, such that for example a plurality of partial regions, for example a plurality of photonic integrated circuits of identical type arranged jointly on a wafer, can be tested sequentially.

The evaluation itself can then be carried out in any conventional way. Implementation details of systems such as the system in FIG. 1 will now be explained with reference to the subsequent figures.

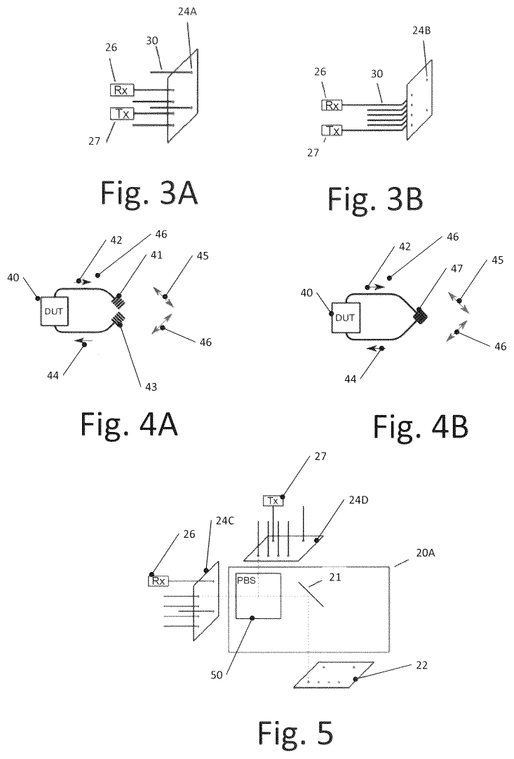

FIG. 2 shows a system in accordance with a further exemplary embodiment. The system in FIG. 2 comprises a measuring unit 28, a microscope 20 and a movable sample stage 210. A wafer 29 having a photonic integrated circuit 22 to be tested is arranged on the sample stage 210. The measuring unit 28 comprises a test card 24, which can correspond to the test card 10 already discussed with reference to FIG. 1 and, like the test card, can be arranged in a corresponding mount. The test card 24 comprises a multiplicity of input/output coupling elements 25 as examples of light outlets and light inlets. Examples of the construction of test cards 24 will be explained in even greater detail further below with reference to FIGS. 3A and 3B. Furthermore, the measuring unit 28 comprises a light source 27 and a detector 26. The light source 27 is connected to output coupling elements of the input/output coupling elements 25, such that light is emitted by the test card 24 at the corresponding output coupling elements. The detector 26 is connected to input coupling elements of the input/output coupling elements 25 and receives light emanating from the photonic integrated circuit 22.

For this purpose, the microscope 20, using a corresponding microscope optical unit, images the test card 24, for example the input/output coupling elements 25 thereof, onto corresponding input/output coupling elements 25 of the photonic integrated circuit 22. The input/output coupling elements 23 of the photonic integrated circuit 22 can be for example grating couplers or other input/output coupling elements that are conventionally used in photonic integrated circuits for example for the purpose of testing. They can also be input/output coupling elements 23 which are used here specifically for testing the photonic integrated circuit 22, while in later normal operation of the photonic integrated circuit 22 other input/output coupling elements are used for coupling in and coupling out light.

In this way, from a plurality of output coupling elements from among the input/output coupling elements 25, light can be brought simultaneously to corresponding input coupling elements 23 of the photonic integrated circuit and light correspondingly emitted in response thereto by the photonic integrated circuit from output coupling elements 23 can be received and can be evaluated via the detector 26. In this case, the detector 26 should be regarded as representative of arbitrary types of detectors and evaluation circuits coupled thereto. The evaluation can be effected for example according to the presence of received light beams or the intensity of the received light beams or can also include more complex measurement methods such as optical time domain reflectometry or optical frequency domain reflectometry, which allows localization of disturbances along a propagation path of the light through the photonic integrated circuit 22.

Optionally, the microscope 20 can include a scanning unit 21, similar to the scanning unit described in DE 102017101626 A1, cited in the introduction. In this regard, for example, an accurate alignment of the imaging via the microscope 20 can be effected, that is to say that the input/output coupling elements 25 can be brought to congruence with the input/output coupling elements 23. By moving the movable stage 210 and/or using the scanning unit 21, it is then possible to successively test for example a plurality of photonic integrated circuits 22 on the wafer 29.

In some exemplary embodiments, the test card 24 is of the same size as the photonic integrated circuit 22. In other embodiments, the test card can be made larger or smaller, but to scale with respect to the photonic integrated circuit 22, and the microscope 20 then ensures a corresponding magnifying or reducing imaging. For example, as a result of a larger embodiment of the test card 24, the production of the test card 24 can be facilitated since more structural space is available, and manufacturing tolerances are permitted to be larger as a result of the scaling, and the test card 24 can then be imaged onto the photonic integrated circuit 22 in correspondingly reduced fashion via the microscope 20. In yet other exemplary embodiments, the test card 24 can also have a topology like a curvature in order to compensate for distortions of an optical unit like the microscope 20. Ultimately, any embodiment of test card 24 and microscope 20 is possible in which the input/output coupling elements 25 are imaged onto the input/output coupling elements 23, or vice versa, such that a desired illumination of the photonic integrated circuit 22 is effected and/or light from the photonic integrated circuit is detected.

Various embodiments of the test card 24 will now be explained with reference to FIGS. 3A and 3B.

FIG. 3A shows a test card 24A constructed via optical fibres 30. Fibre ends of the optical fibres 30 on the test card 24A constitute the input/output coupling elements 25 from FIG. 2. Miniaturized attachment optical units can additionally be applied to the fibre ends in order thus to form the input/output coupling elements 25.

On the side facing away from the microscope 20, arbitrary fibre-coupled measuring systems can then be connected, the detector 26 being one example thereof. In the case of FIG. 3A, a high positioning accuracy and stability of the fibre ends can be achieved via V-shaped depressions or ferrules in a corresponding material such as ceramic, hard metal or suitable plastics, for example. The fibres can be arranged in a row or in a two-dimensional matrix.

FIG. 3B shows a test card 24B which can itself be constructed as a photonic integrated circuit or as an electro-optical circuit board. Electro-optical circuit boards are described for example in DE 102018108283 A1. In the case of an embodiment as a photonic integrated circuit, optical fibres 30 can be connected via grating couplers or edge couplers. As in the exemplary embodiment in FIG. 3A, further measuring systems can then be connected. Such grating couplers or edge couplers can be arranged for example on the side of the test card 24B facing away from the sample. The input/output coupling elements 25 facing the microscope 20 and thus the sample 22 can likewise be realized as grating couplers or edge couplers. In a similar manner, in the case of an embodiment as an electro-optical circuit board of the test card 24B, the optical fibres 30 can be connected by prisms or edge couplers. The sample-side coupling elements 25 can also be realized by prisms or edge couplers.

In the case of FIG. 3B, further functionalities such as light sources, detectors, modulators and spectrometers can also be realized in the test card 24B realized as a photonic integrated circuit or electro-optical circuit board, such that a part or the entire measuring system is realized in the test card 24B itself. In other words, the detector 26 and/or the light source 27 can also be realized directly in the test card 24B, without coupling by the optical fibres 30 being required.

In the case of the exemplary embodiment is discussed above, the light incident on the photonic integrated circuit is spatially separated from the light emanating from the photonic integrated circuit in order thus to achieve a separation between illumination and measurement. In other words, the light is emitted by the test card 24 at input/output coupling elements different from those where it is received. Additionally or alternatively, a separation on the basis of the polarization can be performed. This will be explained with reference to FIGS. 4 to 6.

In the case of photonic integrated circuits, a polarization sensitivity can generally be attained via grating couplers aligned in a corresponding direction. FIG. 4A shows a corresponding example.

FIG. 4A shows a photonic integrated circuit 40 to be tested (DUT, Device Under Test), which is connected to an input coupling grating 43 and an output coupling grating 41 via waveguides. Input coupling grating 43 and output coupling grating 41 can be specific test structures which are used only for testing the photonic integrated circuit. Such structures can be arranged on a wafer on which the photonic integrated circuit 40 is formed, and can be partly separated for example along a sawing line 46 after testing. Two edge couplers for the photonic integrated circuit 40 then arise at the edges of the waveguides at the sawing line. In this case, compared with the grating coupler 41 used for output coupling, the grating coupler 43 used for input coupling of light has an orthogonal alignment of the grating, such that the grating coupler 43 couples in light having a polarization according to an arrow 45, while the grating coupler 41 couples out light having a polarization according to an arrow 46, i.e. having a polarization perpendicular to the polarization of the light coupled in. Arrows 42 and 44 symbolize how the light is guided from the grating coupler 42 to the photonic integrated circuit 40 and from the photonic integrated circuit 40 to the grating coupler 41.

As shown in FIG. 4B, a dual polarization grating coupler 47 can also be used instead of the separate grating couplers 41, 43. Otherwise, FIG. 4B corresponds to FIG. 4A. In the case of FIG. 4B, as in the case of FIG. 4A, two separate edge couplers are then likewise available at the sawing line 46. That is to say that light can then be coupled in and out at the edge.

FIG. 5 shows a system in accordance with one exemplary embodiment, which uses a photonic integrated circuit 22 with polarization-sensitive input and output coupling as explained with reference to FIGS. 4A and 4B FIG. 5 shows a system in which a corresponding polarization separation is realized within a microscope. The system in FIG. 5 comprises a first test card 24C, a second test card 24D and a microscope 20A in order to test the photonic integrated circuit 22, which in this case, as explained with reference to FIGS. 4A and 4B, uses at least for test purposes separate polarizations for input coupling and output coupling, that is to say comprises corresponding test structures. The test card 24C serves for transmitting light from the light source 26, and the test card 24D serves for receiving light and for detecting via the detector 27. Light emanating from the test card 24C passes through a polarization beam splitter 50 with a corresponding polarization to the photonic integrated circuit 22 and is then coupled in by input coupling gratings such as the input coupling grating 43 from FIG. 4A. By contrast, light emanating from the photonic integrated circuit 22 is directed through the polarization beam splitter 50 to the test card 24D and is analysed there. Apart from the polarization beam splitter 50, the microscope 20A corresponds to the microscope 20 in FIG. 2. Compared with solutions which do not use polarized light and use a simple beam splitter, a larger proportion of the light thus passes to the detector 27 and can be evaluated.

Apart from the polarization separation and the use of separate test cards and the use of different polarizations, the exemplary embodiment in FIG. 5 corresponds to that in FIG. 2, and other details can be implemented as discussed with reference to FIG. 2. The test cards 24C, 24D can each be implemented as discussed with reference to FIGS. 3A and 3B, in which case, in the exemplary embodiment illustrated, only the components for emitting light (e.g. light outlets) are implemented in the test card 24C and only the components for receiving light (e.g. light inlets) are implemented in the test card 24D. In other exemplary embodiments, one of the two test cards 24C, 24D or both test cards 24C, 24D can comprise components for emitting light and also components for receiving light.

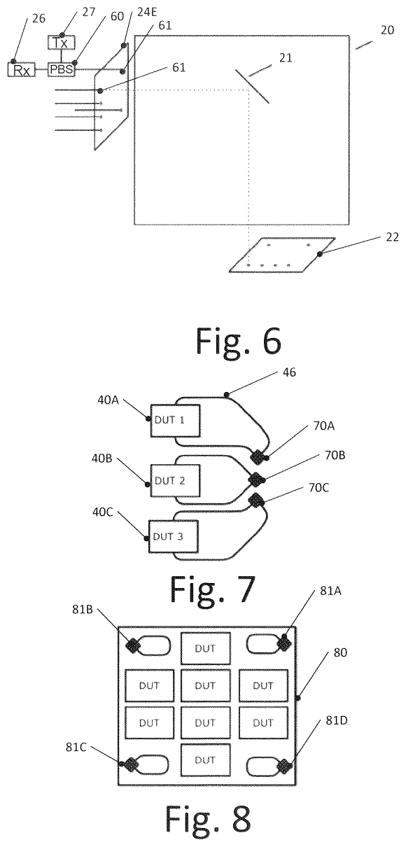

FIG. 6 shows an alternative system. Here a microscope 20 corresponds to the microscope 20 in FIG. 2 and for example does not comprise a polarization beam splitter, in contrast to the microscope 20A in FIG. 5. The system in FIG. 6 further comprises a test card 24E. The test card 24E comprises input/output coupling elements, such as the input/output coupling element 61, at which light is both coupled in and coupled out. These input/output coupling elements 61 are then connected both to the light source 27 and to the detector 26 via a polarization beam splitter 60. Here, therefore, the beam splitting does not take place in the microscope 20, as in the case of FIG. 5, but rather in or downstream of the test card 24E.

As already mentioned, a plurality of photonic integrated circuits to be tested can be provided on a wafer. Coupling gratings connected thereto can be arranged close together. One example is illustrated in FIG. 7. FIG. 7 has four photonic integrated circuits 40A to 40C to be tested, which are connected as illustrated to three dual polarization grating couplers 70a to 70c via corresponding waveguides. In this case, the dual polarization grating couplers 70a to 70c correspond to the dual polarization grating coupler 47 in FIG. 4B. Similar arrangements are also possible with separate input and output coupling grating couplers according to FIG. 4A.

As illustrated in FIG. 7, the dual polarization grating couplers 70a to 70c are situated close together. In this way, overall only a comparatively small chip area on the corresponding wafer is used for the couplers A corresponding test card is then embodied so that light is radiated onto the couplers 70a to 70c and light is received from them. As explained with reference to FIGS. 4A and 4B, after sawing along the sawing line 46, two edge couplers are then in each case available for each of the photonic integrated circuits 40A to 40C. While one light input and one light output (either in combination as a dual polarization grating coupler or with separate grating couplers) are shown for each photonic integrated circuit to be tested in FIGS. 4A and 4B and also in FIG. 7, it is also possible for more than one input coupling element and/or more than one output coupling element to be assigned to one, a plurality or all of the photonic integrated circuits to be tested in other embodiments.

As already briefly explained, for the purpose of testing, the respective test card (for example 24 in FIG. 2) or a plurality of test cards (for example 24C, 24D in FIG. 5) must be correctly aligned in order that the photonic integrated circuit (for example 22) that is respectively to be tested is illuminated at the correct locations or light is gathered from the correct locations. In order to facilitate this alignment, optical alignment markers can be used in some exemplary embodiments. A corresponding exemplary embodiment of a wafer or chip 80 to be tested and having a multiplicity of photonic integrated circuits to be tested is shown in FIG. 8. In FIG. 8, four dual polarization grating couplers 81A to 81D are provided, which are short-circuited with themselves by a respective waveguide, that is to say that incident light is emitted directly again with altered polarization. This can be correspondingly tested using the systems from FIGS. 5 and 6, that is to say that it is possible to test whether light which emerges from the test card 24E from FIG. 6 or the test card 24C from FIG. 5 at the points assigned to the couplers 81A to 81D is received at corresponding points of the test card 24E from FIG. 6 (the identical points in that case) or the test card 24D from FIG. 5. In this case, two coupling elements 81A to 81D are used for a two-dimensional alignment, three coupling elements are used for a three-dimensional alignment, and it is also possible to provide more coupling elements, for example 4 coupling elements, as shown in FIG. 8.

Various variations of the systems discussed above are possible.

Instead of separation on the basis of polarization, in other exemplary embodiments, separation according to direction of propagation, incident light or received light can also be effected if a circulator is used instead of the polarization splitter.

Moreover, a semitransparent mirror or a foldable mirror can be provided in the microscopes 20 and 20A in a conventional manner, which mirror directs light from the photonic integrated circuit onto a camera in order thus to enable an overview image.

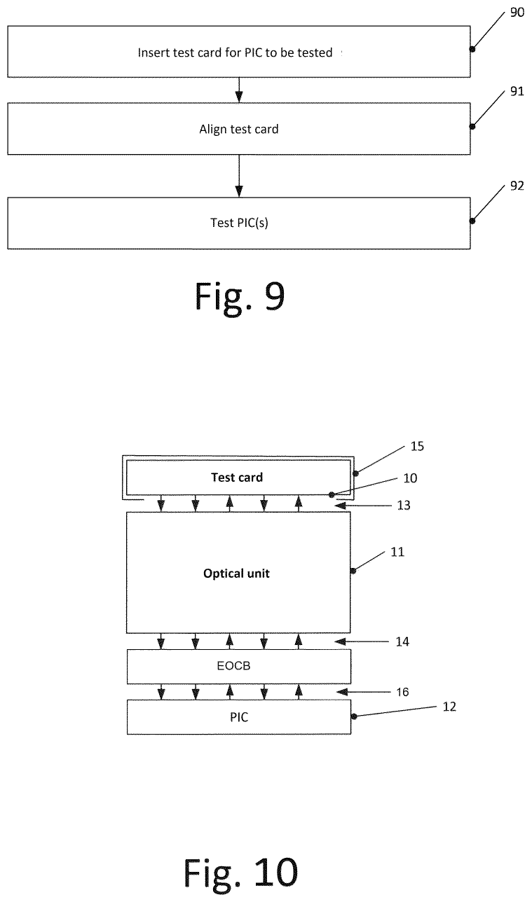

FIG. 9 shows a flow diagram for illustrating a method for testing photonic integrated circuits using the systems described above.

In step 90, a test card such as the test card 10 from FIG. 1, the test card 24 from FIG. 2 or one of the test cards 24A to 24E discussed is inserted into a corresponding apparatus such as the microscope 20, 20A. As desired, in step 91, the test card is then oriented and aligned, for example using the coupling elements 81A to 81D from FIG. 8. The respective photonic integrated circuit is then tested by light being radiated in and, in response thereto, the light being measured, as already described with reference to the apparatuses.

FIG. 10 shows a block diagram of a further system with an additional electro-optical circuit board, in accordance with one exemplary embodiment.

In order to provide an electrical contacting in addition to the optical contacting of the photonic integrated circuit, an electro-optical circuit board (EOCB) can be arranged adjacent to the photonic integrated circuit (PIC). Such electro-optical circuit boards are described for example in the document DE 10 2018 108 283 A1.

The electro-optical circuit board can comprise at least one electrical conductor track extending between a front side of the electro-optical circuit board and a rear side of the electro-optical circuit board and configured to contact an electrical interface of the photonic integrated circuit positioned adjacent to the rear side, and can further comprise at least one optical beam path extending between the front side of the electro-optical circuit board and the rear side of the electro-optical circuit board and configured to contact an optical interface of the photonic integrated circuit positioned adjacent to the rear side.

As can be seen in FIG. 10, the electro-optical circuit board can be arranged on the photonic integrated circuit, such that both electrical and optical signals can be passed on between the electro-optical circuit board and the photonic integrated circuit by the electro-optical circuit board, as is indicated by the arrows 16. In this case, the optical unit 11 images the test card 10 onto the electro-optical circuit board, such that the electro-optical circuit board is illuminated at points corresponding to the light outlets of the test card 10, as is indicated by the arrows 14, and passes on the optical signals to the photonic integrated circuit. Correspondingly, the electro-optical circuit board can receive light emitted by the photonic integrated circuit 12 in response to illumination and can pass it on to the optical unit 11, or the test card 15, as is also indicated by arrows 14. Consequently, the electro-optical circuit board passes on optical signals between the test card 15 and the photonic integrated circuit 12, and additionally provides an electrical contacting of the photonic integrated circuit.

In a further exemplary embodiment, the electro-optical circuit board, or alternatively a purely electrical circuit board, can also be arranged on an opposite side of the photonic integrated circuit with respect to the optical unit 11. Consequently, the photonic integrated circuit can be contacted purely optically on a side of the photonic integrated circuit facing the optical unit 11, and can additionally be contacted purely electrically from a side of the photonic integrated circuit facing away from the optical unit 11. In this case, the electrical and optical contacting of the photonic integrated circuit can be effected as described in the document DE 10 2018 108 283 A1.

The use of an electro-optical circuit board enables particularly simple contacting of the photonic integrated circuit. By way of example, a topography of the rear side of the electro-optical circuit board can be adapted to a topography of the photonic integrated circuit. This means that a lateral arrangement of optical coupling points formed by the at least one optical beam path is adapted to a topography of the optical interfaces of the photonic integrated circuit. In the case of a high integration density of the photonic integrated circuit, this can mean that an average distance between adjacent coupling points at the rear side of the electro-optical circuit board is comparatively small, for example is in the micrometres range. For example, the average distance between the coupling points at the rear side can be smaller than an average distance between coupling points at the front side of the electro-optical circuit board. This can make it possible, in an automated manner, to produce an optical contact with the photonic integrated circuit via the coupling points on the front side of the electro-optical circuit board particularly reliably because only a comparatively lower positioning accuracy is involved in order to image the test card onto the electro-optical circuit board according to the optical coupling points.

1. An apparatus, comprising:
a first receptacle for a first test card comprising a plurality of light ports; and
an optical unit configured to image the test card onto a photonic integrated circuit.

2. The apparatus of claim 1, further comprising a second receptacle for a second test card comprising light inlets, wherein the optical unit comprises a splitter element configured to: i) pass light from first test card to the photonic integrated circuit; and ii) pass light from the photonic integrated circuit to the second test card.

3. The apparatus of claim 2, wherein the splitter element comprises a polarization beam splitter.

4. The apparatus of claim 1, further comprising a scanner device in a light path from the first receptacle to the photonic integrated circuit.

5. A system, comprising:
an apparatus according to claim 1; and
a test card comprising a multiplicity of light outlets configured to illuminate the photonic integrated circuit, the light outlets disposed in a manner corresponding to locations of the photonic integrated circuit that are to be illuminated for the purpose of testing,
wherein the test card is in the first receptacle.

6. The system of claim 5, wherein:
the apparatus further comprises a second receptacle for a second test card comprising light inlets;
the optical unit comprises a splitter element configured to: i) pass light from first test card to the photonic integrated circuit; and ii) pass light from the photonic integrated circuit to the second test card;
the test card further comprises a multiplicity of light inlets configured to receive light from the photonic integrated circuit;
the light inlets are arranged in a manner corresponding to light-emitting locations of the photonic integrated circuit which are configured to emit light during testing of the photonic integrated circuit; and
the test card is in the second receptacle.

7. The system of claim 5, wherein the optical unit comprises a splitter element configured to: i) pass light from first test card to the photonic integrated circuit; and ii) pass light from the photonic integrated circuit to the second test card.

8. The system of claim 7, wherein the splitter element comprises a polarization beam splitter.

9. The system of claim 5, wherein the apparatus further comprises a scanner device in a light path from the first receptacle to the photonic integrated circuit.

10. The system of claim 5, further comprising a circuit board configured to contact the photonic integrated circuit, wherein the circuit board comprises an electrical conductor track extending between a front side of the circuit board and a rear side of the circuit board, and electrical conductor track is configured to contact an electrical interface of the photonic integrated circuit positioned adjacent to the rear side.

11. A method of testing a photonic integrated circuit, comprising:
providing an apparatus according to claim 1;
inserting into the receptacle a test card comprising a multiplicity of light outlets configured to illuminate a photonic integrated circuit, the light outlets disposed in a manner corresponding to locations of the photonic integrated circuit that are to be illuminated for the purpose of testing;
aligning the test card; and
testing the photonic integrated circuit using the test card.

12. A test card, comprising:
a multiplicity of light outlets configured to illuminate a photonic integrated circuit,
wherein the light outlets are disposed in a manner corresponding to locations of the photonic integrated circuit that are to be illuminated for the purpose of testing.

13. The test card of claim 12, further comprising a light source and an optical fibre, wherein the optical fibre connects the light outlets and the light source.

14. The test card of claim 13, wherein the light outlets correspond to ends of the optical fibre.

15. The test card of claim 14, wherein the test card comprises the photonic integrated circuit.

16. The test card of claim 12, wherein the test card comprises the photonic integrated circuit.

17. The test card of claim 12, wherein the test card comprises an electro-optical circuit board.

18. The test card of claim 12, wherein the light outlets are configured to output polarized light.

19. The test card of claim 12, further comprising a multiplicity of light inlets configured to receive light from the photonic integrated circuit, wherein the light inlets are arranged in a manner corresponding to light-emitting locations of the photonic integrated circuit which are configured to emit light during testing of the photonic integrated circuit.

20. A test card, comprising:
a multiplicity of light inlets configured to receive light from a photonic integrated circuit,
wherein the light inlets are arranged in a manner corresponding to light-emitting locations of the photonic integrated circuit which are configured to emit light during testing of the photonic integrated circuit.

21.-25. (canceled)
